(19) United States
(12) Patent Application Publication
(10) Pub. No.: US 2011/0036102 A1
(43) Pub. Date: Feb. 17, 2011

(54) CRYOSTAT HAVING A REINFORCED INTERIOR VESSEL

(75) Inventors: Hannes Nowak, Jena (DE); Sergio Nicola Ernè, Neu-Ulm (DE)

Correspondence Address: Fanelli Strain & Haag PLLC, 1455 Pennsylvania Ave., N.W., suite 400, Washington, DC, 20004, US

(73) Assignee: BMDSYS PRODUCTION GMBH

(21) Appl. No.: 12/679,179

(22) PCT Filed: Sep. 24, 2008
(86) PCT No.: PCT/EP08/08070

§ 371 Date: Nov. 1, 2010

(30) Foreign Application Priority Data
Sep. 24, 2007 (EP) 07018698.6

(51) Int. Cl. F17C 3/08; F17C 1/16; B27N 3/14; G01R 33/02

(52) U.S. Cl. 62/51.1; 264/255; 324/244

(57) ABSTRACT

A cryostat (110) for use in a biomagnetic measurement system is proposed. The cryostat (110) comprises at least one inner vessel (112) and at least one outer vessel (114), and at least one cavity (126) arranged between the inner vessel (112) and the outer vessel (114), in which negative pressure can be applied to the cavity (126). The inner vessel (112) has a base part (136) and a sidewall (134) connected to the base part (136) in a circumferential connection region (140). The inner vessel (112) has a circumferential strengthening element (142) in the connection region (140), with the strengthening element (142) having a first fiber composite material with a first fibrous material (158) with an anisotropic orientation and with a local preferred orientation, the local preferred orientation being oriented substantially in the circumferential direction of the cryostat (110).

### FIELD OF THE INVENTION

The invention relates to a cryostat particularly suitable for use in a biomagnetic measurement system and a biomagnetic measurement system comprising such a cryostat. The invention furthermore relates to a method for producing a cryostat particularly suitable for biomagnetic measurements. Such cryostats and measurement systems can be used, in particular, in the field of cardiology, or else in other fields of medicine, such as neurology. Other applications, for example non-medical applications, for example applications in materials science, are also feasible.

### PRIOR ART

In recent years and decades, magnetic measurement systems, which were previously restricted in essence to use in basic research, found their way into many areas of the biological and medical sciences. Neurology and cardiology in particular profit from such biomagnetic measurement systems.

Biomagnetic measurement systems are based on most cell activities in the human or animal body being connected with electrical signals, in particular electrical currents. The direct measurement of such electrical signals caused by cell activity is known, for example, from the field of electrocardiography. However, in addition to the purely electrical signals, the electrical currents are also connected with a corresponding magnetic field, the measurement of which is used by the various known biomagnetic measurement methods.

Whereas the electrical signals, or the measurement thereof outside of the body, are connected with different factors such as the different electrical conductivities of the tissue types between the source and the body surface, magnetic signals penetrate these tissue regions almost unhindered. Measuring these magnetic fields and the changes therein thus allows conclusions to be drawn about the currents flowing within the tissue, e.g. electrical currents within the myocardium. Measuring these magnetic fields over a certain region with a high temporal and/or spatial resolution thus allows imaging methods that, for example, can reproduce a current situation in different regions of a human heart. Other known applications are found, for example, in the field of neurology.

However, measuring the magnetic fields of biological samples or patients, or measuring temporal changes in these magnetic fields constitutes a large metrological challenge. Thus, by way of example, the changes in the magnetic field in the human body, which should be measured in magnetocardiography, are approximately one million times weaker than the Earth's magnetic field. Thus, detecting these changes requires extremely sensitive magnetic sensors. Thus, superconducting quantum interference devices (SQUIDs) are used in most cases in the field of biomagnetic measurements. In general, such sensors typically have to be cooled to 4K (−269° C.) to attain or maintain the superconducting state for which purpose liquid helium is usually used. Therefore, the SQUIDs are generally arranged individually or in a SQUID array in a so-called Dewar flask and are correspondingly cooled at said location. As an alternative, laser-pumped magneto-optic sensors are currently being developed, which can have an almost comparable sensitivity. In this case, the sensors are also generally arranged in an array arrangement in a container for the purposes of stabilizing the temperature.

Such containers for stabilizing the temperature, in particular containers for cooling magnetic sensors and so-called Dewar flasks, are in general referred to as “cryostats” in the following text. In particular, these can be helium cryostats or other types of cryostats. Herein, no distinction is made in the following text between the cryostat and the cryostat vessel, which is also referred to as Dewar, even though the actual cryostat can comprise further parts in addition to the cryostat vessel.

It is a big challenge in terms of the design to produce the cryostat for holding biomagnetic sensor systems. The sensors are usually introduced into this cryostat in a predetermined arrangement, for example in the form of a hexagonal arrangement of SQUIDs or other magnetic sensors. Here, the cryostat usually comprises an inner vessel, with sensors held therein, and an outer vessel. The interspace between the inner vessel and the outer vessel is evacuated. However, in the process, it is very important for the distance between the sensors held in the inner cryostat vessel and the surface of the skin of the patient to be kept as small as possible, because, for example, the signal strength reduces with a high power of the distance between the sensor and the surface of the skin. Accordingly, the distance between the bases of the inner and outer vessels has to remain small and very constant.

The prior art has disclosed many cryostats that can be used for magnetic measurements. Thus, for example, WO 94/03754 describes a cryostat vessel with an inner Dewar and an outer Dewar. Here, a number of radiation shields are provided. DE 298 09 387 U1 also describes a cryostat for radiomagnetic probing methods, in which SQUIDs are preferably used. The cryostat has high electromagnetic transparency at high frequencies. Here, a double vessel is proposed in turn, wherein a sensor is held on the base of an inner vessel. This inner vessel is of a two-part design and discloses that a base part has an elevated edge, which partially surrounds a sidewall.

However, the conventional cryostats used for magnetic measurements in practice have a multiplicity of disadvantages and difficulties, which can have an effect on the reliability and reproducibility of the measurements. Thus, deformations can occur for example when evacuating the interspace between the inner and outer vessel, which can lead right up to the formation of heat bridges between the bases of the vessels. In addition it has been shown that distortions can easily appear, particularly in the transition region between the base part and the sidewall of the inner vessel, and these distortion can cause cracks, which in turn can have a strong negative influence on the quality of the cryostat.

### OBJECT OF THE INVENTION

It is therefore an object of the present invention to provide a cryostat that is particularly suitable for use in biomagnetic measurement systems and that at least substantially avoids the disadvantages of the cryostats known from the prior art. In particular, producing the cryostat in a reliable and reproducible fashion should be possible and the aforementioned problems with the quality should be avoided.

### DESCRIPTION OF THE INVENTION

This object is achieved by a cryostat and a method for producing a cryostat with the features of the independent claims. Advantageous developments of the invention, which can be implemented on their own or can be combined, are illustrated in the dependent claims. The wording of all claims is hereby incorporated in the description by reference.

A cryostat for use in a biomagnetic measurement system is proposed, which cryostat has at least one inner vessel and at least one outer vessel, and at least one cavity arranged between the inner vessel and the outer vessel. Provision can analogously be made for a plurality of such inner and/or outer vessels and/or a plurality of cavities. Negative pressure should be able to be applied to the cavity, that is to say it should be possible to seal said cavity in order to make it possible to evacuate it. For this purpose, the inner and outer vessel for example can have appropriate seals (for example separate sealing rings and/or sealing bonds at connecting points, or similar types of seals), a pump connection for the connection to an apparatus for generating a vacuum (e.g. a vacuum pump), or the like.

In the process, the outer vessel and the inner vessel can be produced from a multiplicity of possible materials ensuring the required mechanical stability of these vessels. It is particularly preferred for these vessels to be produced wholly or partly from a fibrous composite material, that is to say a composite made of a fibrous material and a matrix to material made of a plastic. However, alternatively or additionally, a multiplicity of additional materials can also be used, such as metals, plastics, ceramics or a combination of these materials.

The inner vessel has a base part and a sidewall connected to the base part in a circumferential connection region. This modular design was found to be advantageous over integral designs because this already affords the possibility of avoiding much of the tension in the transition region between the base and the sidewalls.

In order additionally to obtain a strengthening in the connection region between the base part and sidewall as well, it is proposed, according to the invention, that the inner vessel has a circumferential strengthening element in the connection region. This strengthening element should have a first fiber composite material with a first fibrous material with an anisotropic orientation and with a local preferred orientation. This local preferred orientation should be oriented substantially in the circumferential direction of the cryostat. In other words, the fibrous material comprises fibers, which are substantially arranged tangentially at every position of the strengthening element. Here, “substantially” should be understood as meaning an oriented alignment of the fibers, which is at least 10%, preferably at least 20%. Also, the local preferred direction of the fibers of the fibrous material preferably should deviate by less than 20° from the circumferential direction, preferably by even less than 10° or less than 5°. However, the option of the fiber material comprising a fiber mat or a fibrous tissue should not be precluded by this. By way of example, a fibrous tissue can have warp threads and weft threads. Here, the warp threads or weft threads should, for example, be oriented substantially in the circumferential direction, whereas the respective other type of thread is oriented perpendicular thereto, for example parallel to an axis of the cryostat. In this respect, preferably at least 40% or even at least half of the fibers are substantially oriented in the circumferential direction in this example. The fiber mats as a whole should likewise have a tangential orientation in their longitudinal extent. If an elongate band of a fiber mat is used, for example within the scope of a winding technique, the longer axis of this band should preferably run in the circumferential direction.

The proposition relating to the strengthening elements is based on the fact that numerous trials with fiber composite materials have shown that the arbitrary arrangement of the fibers in fiber composite materials can result in significant problems in the connection region. Thus, for example, methods in which the fiber alignment is substantially aligned in a radial arrangement can be used for producing the base part. However, instabilities in the vessel wall may occur, particularly when evacuating the cavity, due to the slight bending of the fibers when a force acts thereon in the radial direction.

By contrast, the proposed strengthening element with the fibers of the fibrous material oriented in the circumferential direction acts like a “strengthening belt” and said element is based on the same basic idea as, for example, a radial tire in automotive technology. The individual fibers of the fibrous material can be interlocking and so the stability of the circumferential strengthening material is additionally increased in the radial direction over outwardly running loads.

This can greatly reduce the above-described problems relating to the quality and stability of the inner vessel in the particularly critical connection region between the base part and the sidewall. There is no noteworthy damage or wear and tear in this region, even after a multiplicity of evacuation processes.

There can be a number of advantageous developments of the proposed cryostat. Thus, for example, the strengthening element can be designed as a separate strengthening element, for example as a belt-shaped, tire-shaped or ring-shaped separate strengthening element. However, it is particularly preferable for the strengthening element to be designed integrally with the sidewall or, even more preferably, integrally with the base part. By way of example, in the latter case, the strengthening element can be a component of an elevated edge of the base part, which is in contact with the sidewall and, for example, is adhesively bonded thereto.

In general, various connection techniques can be used for the connection between the base part and the sidewall, wherein welding, adhesive bonding, casting or other techniques or combinations of these techniques are feasible. However, other techniques also can be used.

In the case where the strengthening element is designed integrally with the base part, it is particularly preferred for the base part also to have a second fiber composite material outside the base part. This second fiber composite material can be, for example, wholly or partly identical in terms of material with the first fiber composite material, i.e. it can have, for example, identical matrix materials and/or identical types of fibrous materials. The second fiber composite material has a fibrous material, which, for example, can have an isotropic orientation or in turn be anisotropic with, for example, a radial orientation.

As described above, it is particularly preferred for the strengthening element to be designed in the shape of a cylindrical ring. In this case, this cylindrical ring can also have steps, such as e.g. a step onto which the sidewall is placed.

As described above, the base part can have an elevated edge, with the edge being oriented substantially parallel to the sidewall. The strengthening element can be an integral component of this elevated edge; for example, it can be an upper region of this elevated edge. As described above, this elevated edge, particularly in the region of the strengthening element, moreover can have a step, with a lower step surface pointing into the interior of the inner vessel. The sidewall can be supported on this lower step surface. By way of example, this makes it possible for the lower region of the sidewall to be enclosed by an elevated ring or collar of the step. It is particularly preferred in this case if this elevated ring of the step, which surrounds the sidewall, contains the strengthening elements.

In principle, the sidewall can have an arbitrary cross section, wherein an axial symmetry about an axis of the cryostat is preferred. Round or polygonal cross sections are particularly preferred in this case, such that the sidewall for example can be produced as a hollow cylinder with circular or polygonal cross section.

In particular, the first fibrous material and/or possibly the second fibrous material as well can have at least one of the following fibrous materials: a glass-fiber material, a carbon-fiber material, a mineral-fiber material. Combinations of these and/or other materials are also possible. As illustrated above, it is particularly preferable for the fibrous material to have a multiplicity of interlocking fibers in the process. It is particularly preferred if the fibrous material comprises at least one fiber mat, which for example can contain fibers oriented substantially in parallel, even with deviations of not more than preferably 10°-20° from parallel still being tolerable. By way of example, this fiber mat then can have an elongate shape, for example the shape of an elongate strip, wherein the fibers then preferably are arranged in parallel to the longitudinal extent of this strip. The fiber mat should extend at least once over the circumference of the strengthening element, with it being particularly preferable for this fiber mat reach around this circumference a number of times. In this case, a winding technique can be used and this can result in a particularly stable strengthening element.

As described above, the fiber composite material furthermore has a matrix material. This matrix material can comprise at least one or more of the following materials: a thermoplastic polymer material; a duroplastic polymer material, in particular an epoxy resin; an elastomeric material. It is particularly preferred if the matrix material comprises an initially deformable (i.e. able to flow, for example) matrix material, which subsequently can be cured, for example by thermal and/or photochemical and/or chemical curing or can be cured simply by waiting. A number of such materials are known in the prior art and can be utilized. Examples of such resins are presented in more detail below.

Furthermore, it is particularly preferred if the base part has a multiplicity of recesses for holding the biomagnetic sensors, which can, for example, be SQUIDs and/or magneto-optical sensors. These recesses should be arranged in the interior of the inner vessel and point to the base side of the cryostat. By way of example, the recesses can be arranged in a hexagonal arrangement and comprise, for example, 64 recesses. However, different numbers of recesses and/or arrangements of recesses are also possible,

Furthermore, a biomagnetic measurement system is proposed, which contains at least one cryostat according to one of the above-described exemplary embodiments, and at least one biomagnetic sensor for detecting a magnetic field. In respect of the design of these sensors, reference can be made to, for example, WO 03/073117A1, EP 0359 864 B1 or other documents from the field of biomagnetic sensors.

Furthermore, a method for producing a cryostat for use in a biomagnetic measurement system is proposed. By way of example, this method can be used to produce a cryostat according to one of the above exemplary embodiments and so reference largely can be made to the description above in respect of possible method variants. The cryostat in turn has at least one inner vessel and at least one outer vessel, and at least one cavity arranged between the inner vessel and the outer vessel, in which negative pressure can be applied to the cavity. The inner vessel in turn has a base part and a sidewall connected to the base part in a circumferential connection region, in which the inner vessel has a circumferential strengthening element in the connection region. The method comprises the following steps:
At least one second fibrous material is introduced into a mold for the base part, in which the mold has a region for producing the strengthening element. The first fibrous material is arranged substantially outside the region for producing the strengthening element.
At least one first fibrous material is introduced into the mold, in which the first fibrous material is arranged substantially inside the region for producing the strengthening element and with the first fibrous material being oriented substantially in the circumferential direction.
At least one curable matrix material is introduced into the mold and cured.

The method steps can be performed in the specified sequence or else in a different sequence or can be performed at overlapping times.

By way of example, the mold can comprise a conventional casting mold (also referred to as a die) for casting processes. However, other molds are also feasible, depending on the utilized production technique.

As described above, a winding technique for example can be used during the introduction of the first fibrous material. Thus, for example, it is possible to use an elongate fiber mat with fibers oriented in the circumferential direction, which fiber mat is arranged in the mold at least once, preferably a number of times, over the entire circumference of the region for generating the strengthening element.

Moreover, for serial use, it is preferred if a multiplicity of different base parts, which can be used for different types of sensors, can be provided for the inner vessel. By way of example, different sensors can be used, which require a respectively different distance from the skin surface of a patient. However, in conventional methods, this modular technique would mean that a new mold would have to be constructed for each sensor system with different sensors, which is connected with significant costs. In order nevertheless to be able to implement the fiber technique described above in a cost-effective manner and also afford the production of a “modular system” for different sensors in the case of the proposed, qualitatively very stable cryostat, it is therefore proposed to generate the recesses for holding the biomagnetic sensors such that the mold has a multiplicity of interchangeable cores. These cores can have the desired negative shape in respect of the recesses and their selection can be made depending on the desired depth of the recesses. This also affords producing cryostats for a multiplicity of sensors in large-scale serial use, which sensors nevertheless have the above-described positive quality properties.

### EXEMPLARY EMBODIMENTS

Further details and features of the invention emerge from the following description of preferred exemplary embodiments in conjunction with the dependent claims. Herein, the respective features can be realized independently or in groups, combined with one another. The invention is not limited to the exemplary embodiments. The exemplary embodiments are illustrated schematically in the figures. Herein, the same reference signs in the individual figures designate identical or functionally identical elements, or elements that correspond in respect of their functions.

In detail:

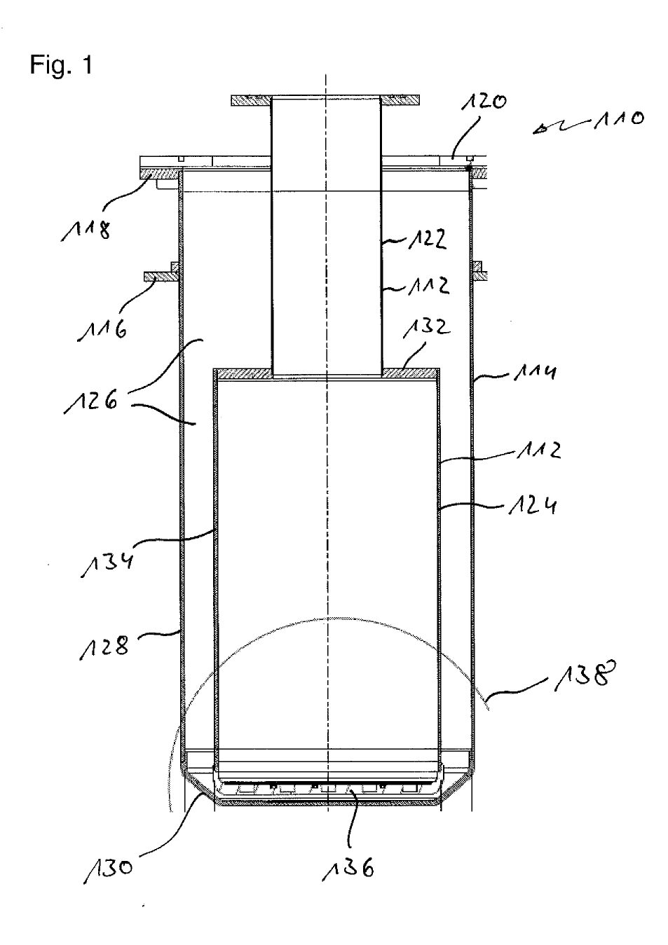

FIG. 1 shows a sectional view of an exemplary embodiment of a cryostat for use in a biomagnetic measurement system;

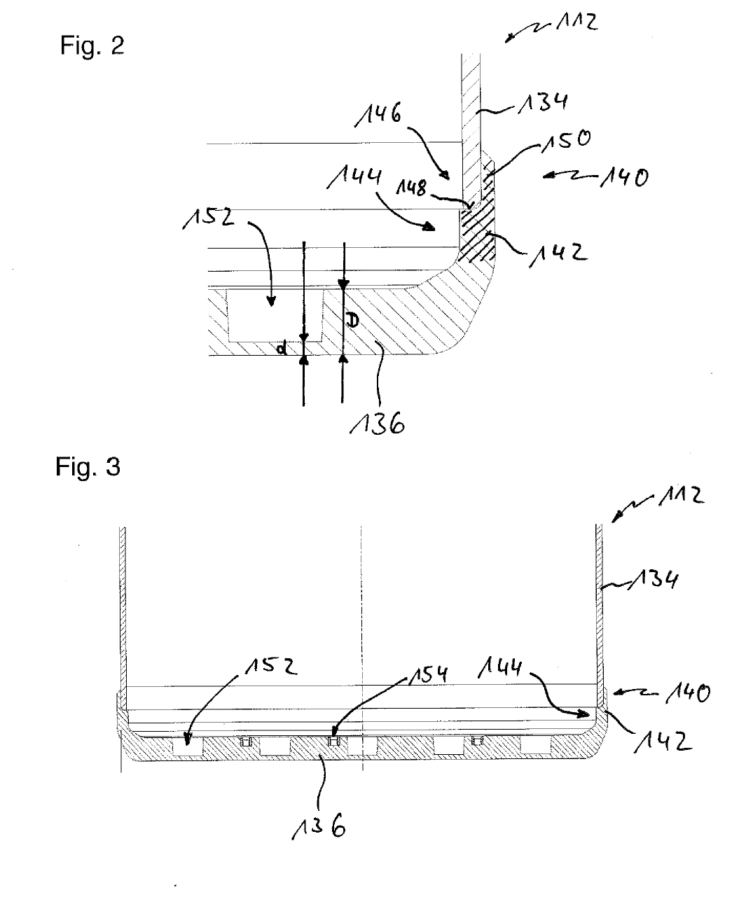

FIG. 2 shows a section of the illustration as per FIG. 1 in the region of a transition between a base part and a sidewall of an inner vessel;

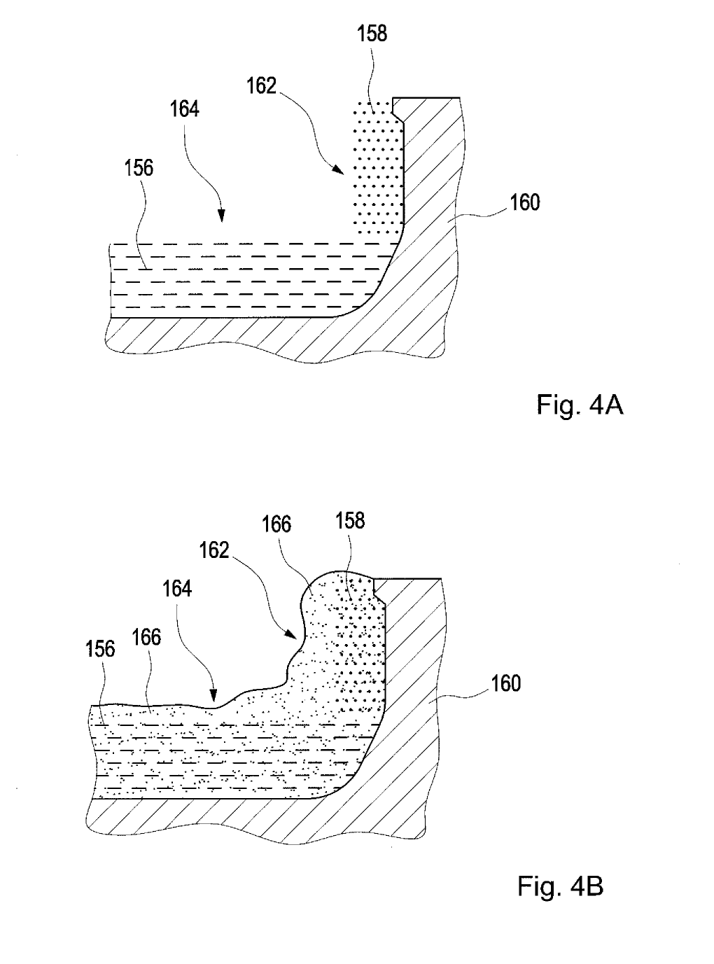

FIG. 3 shows a section from the illustration as per FIG. 1, which shows the base part of the inner vessel; and

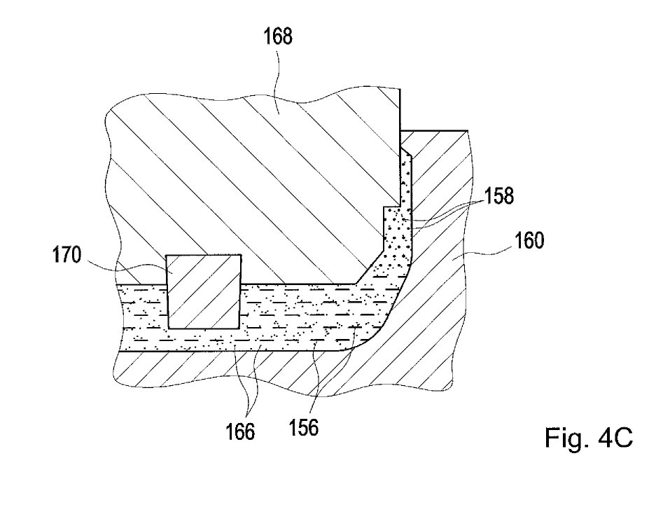

FIGS. 4A-4C show substeps of an exemplary embodiment of a method according to the invention for producing a cryostat for use in a biomagnetic measurement system.

FIG. 1 shows a sectional illustration of a possible exemplary embodiment of a cryostat 110 according to the invention. The cryostat 110 has an inner vessel 112 and an outer vessel 114 surrounding the inner vessel 112.

The outer vessel 114 has a substantially cylindrical design and has various flanges 116 and 118. While the lower of these flanges 116 basically assumes supporting functions, the upper flange 118 serves to hold a cover 120 of the outer vessel 114. A neck 122 of the inner vessel 112 protrudes through this cover 120. This neck 122 can be used to introduce biomagnetic sensors (not illustrated in FIG. 1) into the interior of a (likewise substantially cylindrical) main vessel 124 of the inner vessel 112. Additionally, supply lines to these sensors can be led to the outside through the neck 122 and can be connected to appropriate electronics such that measurement signals of these sensors can be sampled.

A cavity 126 is formed between the inner vessel 112 and the outer vessel 114. This cavity 126 can be evacuated by means of a vacuum connection not illustrated in FIG. 1. As a result of this evacuation and the formation of a negative pressure in this cavity 126, an insulation effect of the cryostat 110 is increased. Thus, the interior space of the main vessel 124 of the inner vessel 112 can be cooled by means of e.g. liquid helium, without an addition to or replacement of this liquid helium being required at short intervals.

Fibrous composite materials are basically used throughout as materials of both the inner vessel 112 and the outer vessel 114. Furthermore, both the inner vessel 112 and the outer vessel 114 have a modular design. Thus, for example, in addition to the cover 120, the outer vessel 114 has a sidewall 128 and a base part 130. The inner vessel 112 has a circular ring 132 in the region of the main vessel 124, which ring seals the neck 122 against the main vessel 124, in addition to the neck 122. Furthermore, the inner vessel 112 has a sidewall 134 and a base part 136. In this exemplary embodiment, the sidewalls 128, 134 have been equipped with a cylindrical shape, but this is not obligatory. Thus, for example, polygonal cross sections or irregular cross sections can also be used.

A particularly critical region in the production of the cryostat 110 is the region of the transition between the base part 136 and the sidewall 134 of the inner vessel 112, which region is labeled by the reference sign 138 in FIG. 1. This region 138 is shown in FIG. 3 in an enlarged detailed illustration. FIG. 2 illustrates a connection region 140 in detail as a further enlarged region. Both figures should be explained together in the following text.

During the evacuation of the cavity 126 in FIG. 1, a force directed outward toward the cavity 126, acts on the sidewall 134 of the inner vessel 112. This force causes tensions in the circumferential connection region 140 between the base part 136 and the sidewall 134 of the inner vessel 112. In order to avoid the formation of cracks in this connection region 140 due to these tensions, the connection region 140 has a circumferential strengthening element 142, which, in this exemplary embodiment, is formed integrally with the base part 136. The base part 136 has an elevated edge 144 in the form of a circular ring, which is formed as a step 146 in its upper region. This step 146 has a lower step surface 148, which bears the lower edge of the sidewall 134 of the inner vessel 112. The step 146 furthermore contains a collar 150, which surrounds the lower edge of the sidewall 134 in an annular fashion.

The strengthening element 142 is basically distinguished from the remainder of the base part 136 by means of its structural properties. Thus, the entire base part 136 is produced from a fibrous composite material, which preferably comprises an epoxy resin as matrix material and, for example, glass fibers as fibrous material. In addition, further additives can be comprised. In the region of the strengthening element 142, this fibrous material, not illustrated in FIGS. 2 and 3, is oriented in the circumferential direction and thus points into the plane of the drawing in FIG. 2. By contrast, the orientation of the fibers of the fibrous material in the remaining base part 136 runs substantially radially, that is to say parallel to the plane of the drawing in FIG. 2. The orientation of these fibrous materials will still be explained in more detail below on the basis of FIGS. 4A-4C.

FIGS. 2 and 3 furthermore show that the base part 136 has a number of recesses 152. These recesses 152 are used to hold biomagnetic sensors, which are not illustrated in the figures. By way of example, SQUIDS can be used for this purpose, which, for example, are mounted on rods introduced into the main vessel 124 through the neck 122 of the inner vessel 112. The base part 136 can hold the biomagnetic sensors in, for example, a hexagonal arrangement and so said sensors can record measurement signals over a surface region and are thus, for example, able to chart a chest region of a patient. By way of example, the recesses 152 are used to fix the biomagnetic sensors and additionally to reduce the distance between the sensor and the skin surface of the patient such that the effective base thickness of the base part 136 is reduced from originally D to the distance d in FIG. 2. Furthermore, in the base part 136, there are thread bores 154 onto which for example rods for supporting the biomagnetic sensors can be fixed.

FIGS. 4A-4C illustrate substeps of a method for producing a cryostat, for example a cryostat as per the above FIGS. 1 to 3. Here, it is only the substeps of the method leading to the production of the base part 136 that are shown, and in these substeps, it is in turn only a section that is shown in each case, which basically corresponds to the section as per FIG. 2 and thus, in particular, comprises the strengthening element 142.

In a first method step as per FIG. 4A, a fibrous material 156 is arranged in a first mold half 160. This first mold half 160 substantially corresponds to the subsequent outer contour of the base part 136, for example as per FIG. 2.

Two regions should be distinguished within the first mold half 160: a first region 162, in which the strengthening element 142 will be created later, and a second region 164, which comprises the base part 136 outside of the strengthening element 164. In this exemplary embodiment, it is assumed that the fibrous material 156, 158 is a mat-shaped fibrous material, with, for example, it being possible that identical fibrous materials 156, 158 are used for both regions 162, 164.

During production, the two regions 162, 164 basically differ in respect of the alignment of the fibrous material 156, 158. Whist, in the region 164, the fibrous material is inserted into the first mold half 160 with basically a radial alignment, the fibrous material 158 is oriented in the circumferential in the region 162 in which the strengthening element 142 will be created later. By way of example, in this example, fiber mats with parallel, interlocking fibers can be pressed into this region 162 of the first mold half 160 such that the fiber mats encircle the elevated edge of this first mold half 160 a number of times. This technique can be referred to as a “winding technique”. However, the fiber mats 156 can also at least partly protrude into the region 162.

FIG. 4B shows how, as the next method step, the fibrous material 156, 158 is cast with a curable matrix material 166. This matrix material 166 for example can be a curable epoxy resin. A possible exemplary embodiment uses an epoxy resin of the type L 20 (as distributed by e.g. R&G Faserverbundwerkstoffe GmbH, 71107 Waldenbuch, Germany) with a hardener, for example of the type EPH 161 (likewise distributed by e.g. R&G Faserverbundwerkstoffe GmbH, 71107 Waldenbuch, Germany). The two-component adhesive Stycast 2850 FT (AAT Aston GmbH, Nuremberg, Germany) constitutes a further possible utilizable example, wherein e.g. the catalyst 9 (likewise AAT Aston GmbH, Nuremberg, Germany) can be used as a hardener. By way of example, an E-glass with a glass cloth with a density of 160 g/m² (as distributed by e.g. R&G Faserverbundwerkstoffe GmbH, 71107 Waldenbuch, Germany) can be used as fibrous material 156, 158. However, it is understood that other types of fibrous materials 156, 158 and/or curable matrix materials 166 can be used as well.

Subsequently, as illustrated in FIG. 4C, a second mold half 168 is pressed onto the first mold half 160. In the process, the matrix material 166 and the fibrous material 156, 158 are pressed together, wherein openings for example can be provided, through which the excess matrix material 166 can escape the cavity between the two mold halves 160, 168. The interaction of the two mold halves 160, 168 basically gives the inner region between these mold halves the shape of the subsequent base part 136. The matrix material 166 can now cure, wherein this curing process for example can comprise a polymerization process, a drying process or the like. The curing can be promoted e.g. by thermal activation, by chemical activation, by photochemical activation or the by addition of initiators. However, simply waiting is also possible. The precise refinement of the curing process in general depends on the selection of the matrix material 166. This forms the base part 136 during curing, which can, for example, be designed as illustrated in FIG. 2, comprising the strengthening element 142 in the connection region 140.

Furthermore, FIG. 4C illustrates an additional, optional method variation, in which the recesses 152 as per FIGS. 2 and 3 can be produced. For this purpose, the second mold half 168 has a plurality of interchangeable cores 170, which constitute a negative of these recesses 152. By way of example, a multiplicity of cores 170 can be made available by one and the same second mold half 168, for example for being able to produce cryostats 110 with varying depths of the recesses 152 (i.e. varying variable d in FIG. 2). A variation in this variable d, i.e. the depth of the recess 152, moreover only has an insignificant effect on the stability of the connection region 140 between the base part 136 and the sidewall 134 of the inner vessel 112, since this stability is substantially due to the strengthening element 142, which acts as a strengthening belt.

### LIST OF REFERENCE SIGNS

110 Cryostat
112 Inner vessel
114 Outer vessel
116 Flange
118 Flange
120 Cover
122 Neck of the inner vessel
124 Main vessel
126 Cavity
128 Sidewall of outer vessel
130 Base part of outer vessel
132 Circular ring
134 Sidewall of inner vessel
136 Base part of inner vessel
138 Critical region
140 Connection region
142 Strengthening element
144 Elevated edge
146 Step
148 Step surface
150 Collar
152 Recesses
154 Thread bores
156 Fibrous material
158 Fibrous material
160 First mold half
162 Region of the strengthening element
164 Region outside the strengthening element
166 Matrix material
168 Second mold half
170 Interchangeable core

1-21. (canceled)

22. A cryostat for use in a biomagnetic measurement system, comprising at least one inner vessel and at least one outer vessel, and at least one cavity arranged between the inner vessel and the outer vessel, in which negative pressure can be applied to the cavity, with the inner vessel having a base part and a sidewall connected to the base part in a circumferential connection region, wherein the inner vessel has a circumferential strengthening element in the connection region, with the strengthening element having a first fiber composite material with a first fibrous material with an anisotropic orientation and with a local preferred orientation, the local preferred orientation being oriented substantially in the circumferential direction of the cryostat.

23. The cryostat as claimed in claim 22, wherein the local preferred direction over the entire circumference of the strengthening element deviates by less than 20° from the circumferential direction.

24. The cryostat as claimed in claim 22, wherein the first fibrous material with an anisotropic orientation has a degree of orientation of at least 20%.

25. The cryostat as claimed in claim 22, wherein the strengthening element is designed to be integral with a base part or the sidewall.

26. The cryostat as claimed in claim 25, wherein the strengthening element is designed to be integral with a base part, the base part having a second fiber composite material outside the strengthening element.

27. The cryostat as claimed in claim 26, wherein the second fiber composite material has a second fibrous material with a substantially isotropic or radially anisotropic orientation.

28. The cryostat as claimed in claim 26, wherein the fiber composite material and the second fiber composite material basically have identical materials.

29. The cryostat as claimed in claim 22, wherein the strengthening element is designed in the shape of a cylindrical ring.

30. The cryostat as claimed in claim 22, wherein the base part has an elevated edge, with the edge being oriented substantially parallel to the sidewall.

31. The cryostat as claimed in claim 30, wherein the strengthening element is an integral component of the elevated edge.

32. The cryostat as claimed in claim 30, wherein the elevated edge has a grading with a lower step surface pointing into the interior of the inner vessel, with the sidewall sitting on the step surface.

33. The cryostat as claimed in claim 22, wherein the sidewall has a round or polygonal cross section.

34. The cryostat as claimed in claim 22, wherein the first fibrous material comprises at least one of the following fibrous materials:
a glass-fiber material;
a carbon-fiber material;
a mineral-fiber material.

35. The cryostat as claimed in claim 22, wherein the first fibrous material has a multiplicity of interlocking fibers.

36. The cryostat as claimed in claim 22, wherein the first fibrous material comprises at least one fiber mat, which has a longitudinal extent over at least once the circumference of the strengthening element.

37. The cryostat as claimed in claim 22, wherein the fiber composite material furthermore comprises a matrix material, with the matrix material comprising at least one of the following materials:
a thermoplastic polymer material;
a duroplastic polymer material, in particular an epoxy resin;
an elastomeric material.

38. The cryostat as claimed in claim 22, wherein the base part has a plurality of recesses for holding biomagnetic sensors.

39. A biomagnetic measurement system, comprising at least one cryostat according to claim 22, furthermore comprising at least one biomagnetic sensor for detecting a magnetic field.

40. A method for producing a cryostat for use in a biomagnetic measurement system, wherein the cryostat has at least one inner vessel and at least one outer vessel, and at least one cavity arranged between the inner vessel and the outer vessel, in which negative pressure can be applied to the cavity, with the inner vessel having a base part and a sidewall connected to the base part in a circumferential connection region, in which the inner vessel has a circumferential strengthening element in the connection region, in which the method comprises the following steps:
at least one second fibrous material is introduced into a mold for the base part, in which the mold has a region for producing the strengthening element, with the second fibrous material being arranged substantially outside the region for producing the strengthening element:
at least one first fibrous material is introduced into the mold in which the first fibrous material is arranged substantially inside the region for producing the strengthening element, with the first fibrous material being oriented substantially in the circumferential direction;
at least one curable matrix material is introduced into the mold and cured.

41. The method as claimed in claim 40, wherein the first fibrous material comprises at least one elongate fiber mat, with the elongate fiber mat being arranged during the introduction into the mold such that said mat extends at least once, preferably a number of times, over the entire circumference of the region for producing the strengthening element.

42. The method as claimed in claim 40, wherein the base part has a plurality of recesses for holding biomagnetic sensors, with the mold comprising a plurality of interchangeable cores for producing the recess, different cores being used for producing different depths in the recesses.
